(19) United States
(12) Patent Application Publication
(10) Pub. No.: US 2018/0082882 A1
(43) Pub. Date: Mar. 22, 2018

(54) Wafer Chuck, Use of the Wafer Chuck and Method for Testing a Semiconductor Wafer

(71) Applicant: Infineon Technologies AG, Neubiberg (DE)

(72) Inventors: Rudolf Zelsacher, Klagenfurt (AT); Peter Irsigler, Obernberg/Inn (AT); Thomas Christian Neidhart, Klagenfurt (AT)

(21) Appl. No.: 15/701,126

(22) Filed: Sep. 11, 2017

(30) Foreign Application Priority Data
Sep. 20, 2016 (DE) 102016117682.6

(51) Int. Cl. H01L 21/687; G01R 31/28; B25B 11/00

(52) U.S. Cl. CPC H01L 21/68785; G01R 31/2874; G01R 31/2891; G01R 31/2865; B25B 11/005

(57) ABSTRACT

A wafer chuck configured to support a wafer during a wafer test procedure comprises a contact portion for supporting the wafer while being in contact with the wafer. The contact portion is made of a conductive material, the conductive material having a melting point larger than 1500° C.

### CROSS-REFERENCE TO RELATED APPLICATIONS

This application claims priority to German patent application No. 102016117682.6, filed on Sep. 20, 2016, which application is hereby incorporated herein by reference in its entirety.

### TECHNICAL FIELD

The present application relates to semiconductors, and in particular to a wafer chuck, use of the wafer chuck and method for testing a semiconductor wafer.

### BACKGROUND

During semiconductor device fabrication, wafer testing is carried out before the semiconductor wafer is cut into a plurality of individual semiconductor chips or dies. Wafer testing aims at identifying functional defects of the discrete semiconductor devices and/or integrated circuits in the semiconductor wafer and is typically carried out by a test equipment called a wafer prober. The wafer prober includes a wafer chuck for mounting the wafer for testing purposes. There is a need of developing improved wafer chucks which enable improved testing methods.

### SUMMARY

Accordingly, various embodiments of the present invention provide an improved wafer chuck, and an improved method for testing a semiconductor wafer.

According to an embodiment, a wafer chuck is configured to support a wafer during a wafer test procedure. The wafer chuck comprises a contact portion for contacting the wafer. The contact portion is made of a conductive material. The conductive material has a melting point larger than 1500° C.

According to an embodiment, a method for testing a semiconductor wafer comprises placing the semiconductor wafer on a wafer chuck as described above, and impressing a current or applying a voltage to terminals electrically connected to the semiconductor wafer.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIG. 1 shows a schematic arrangement of a wafer test equipment.

FIG. 2 shows an example of a portion of a semiconductor wafer placed on a wafer chuck.

FIGS. 3A and 3B illustrate examples of wafer chucks.

FIG. 4 summarizes a method according to an embodiment.

### DETAILED DESCRIPTION OF ILLUSTRATIVE EMBODIMENTS

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “leading”, “trailing” etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

As employed in this specification, the terms “coupled” and/or “electrically coupled” are not meant to mean that the elements must be directly coupled together—intervening elements may be provided between the “coupled” or “electrically coupled” elements. The term “electrically connected” intends to describe a low-ohmic electric connection between the elements electrically connected together.

The terms “wafer”, “substrate” or “semiconductor substrate” used in the following description may include any semiconductor-based structure that has a semiconductor surface. Wafer and structure are to be understood to include silicon, silicon-on-insulator (SOI), silicon-on sapphire (SOS), doped and undoped semiconductors, epitaxial layers of silicon supported by a base semiconductor foundation, and other semiconductor structures. The semiconductor need not be silicon-based. The semiconductor could as well be silicon-germanium, germanium, or gallium arsenide. According to other embodiments, silicon carbide (SiC) or gallium nitride (GaN) may form the semiconductor substrate material.

The terms “lateral” and “horizontal” as used in this specification intends to describe an orientation parallel to a first surface of a semiconductor substrate or semiconductor body. This can be for instance the surface of a wafer or a die.

The term “vertical” as used in this specification intends to describe an orientation which is arranged perpendicular to the first surface of the semiconductor substrate or semiconductor body.

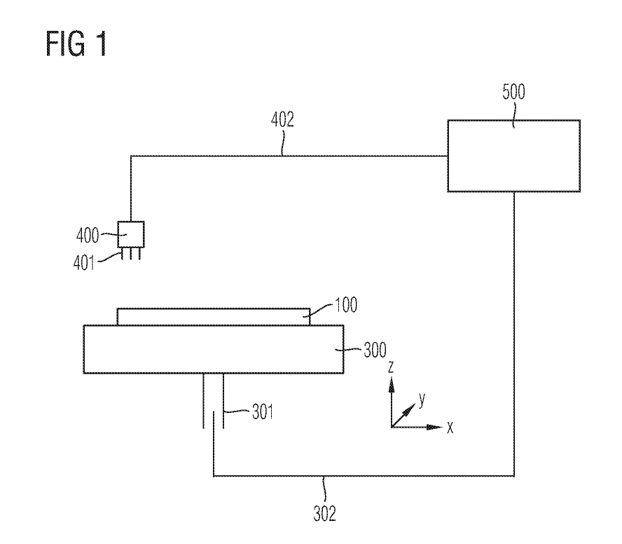

FIG. 1 illustrates an example of a wafer test equipment for performing a wafer test. A wafer 100 is placed on a wafer chuck 300. The wafer chuck 300 may be supported by a chuck support 301. The wafer chuck 300 is electrically connected to an evaluation device 500 by means of a connect element 302. A probe card 400 comprises a plurality of needles 401 which may be used for contacting several devices or a single device formed in the semiconductor wafer 100. The probe card 400 may be connected via a second interconnect 402 to the evaluation device 500.

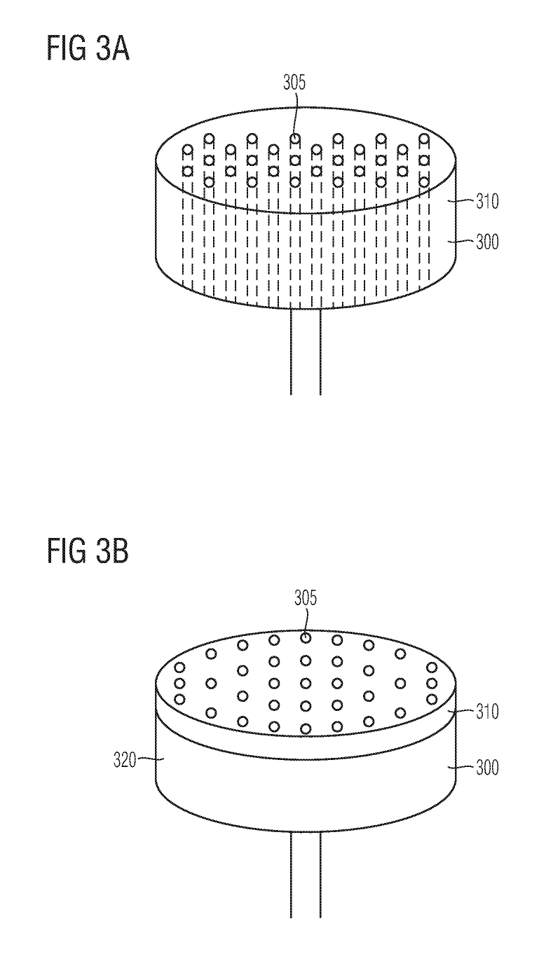

Generally, a plurality of single semiconductor devices such as power transistors, general purpose transistors, memory cells, sensors, further comprising semiconductor components such as diodes, light emitting elements, capacitors and others, which may, for example, constitute integrated circuits, are assigned to single chips arranged in the wafer 100. The manufacture of these semiconductor devices may have been completed. The semiconductor wafer 100 is placed on a wafer chuck 300 which may have a size larger than the size of the semiconductor wafer 100. Small holes 305 (illustrated in FIGS. 3A and 3B) may be arranged in the wafer chuck 300 so as to create a vacuum between the wafer 100 and the wafer chuck 300 to fasten the wafer 100 on the wafer chuck 300. The wafer chuck 300 is movable along three directions, e.g. the x-direction, the y-direction and the z-direction. In particular, the wafer chuck 300 may be moved in a horizontal direction so that a certain chip (group) is placed below the probe card 400. Then, the wafer chuck 300 is moved in a vertical direction towards the probe card 400 so that the needles 401 contact one or more semiconductor chips. For example, the needles 401 may contact the source regions of several transistor cells or transistors.

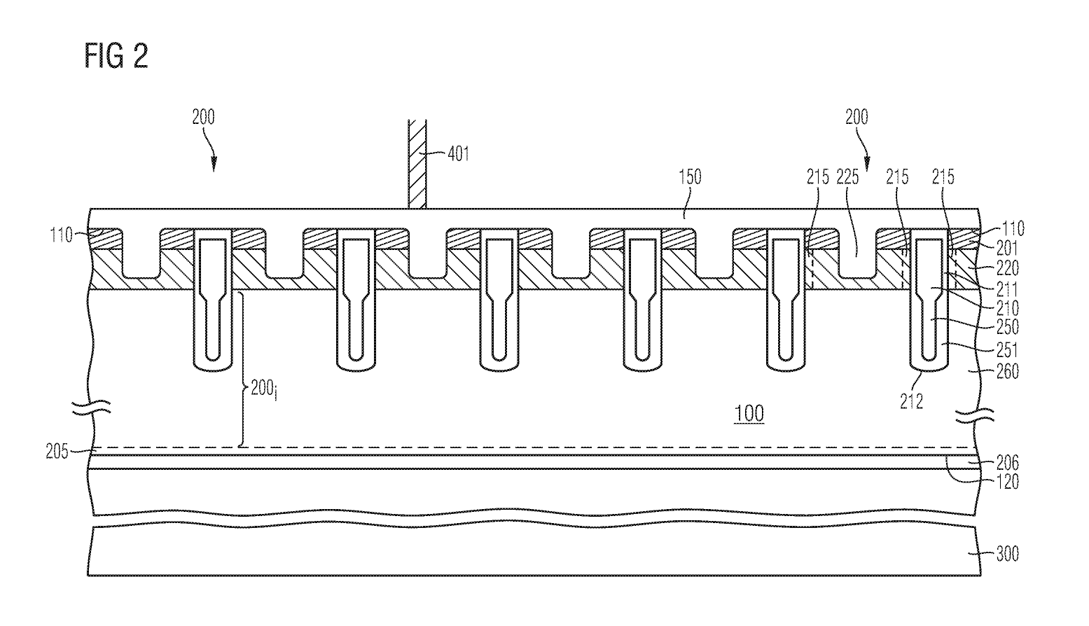

FIG. 2 shows an enlarged view of components of a power transistor in contact with the wafer chuck 300. As is shown, a transistor 200 comprising a plurality of transistor cells 200i that may be connected parallel to each other is arranged in the semiconductor wafer 100. For example, the source region 201 is disposed adjacent to a first main surface 110 of the semiconductor wafer. Further, a drain region 205 of the transistor 200 is arranged adjacent to a second main surface 120 of the semiconductor wafer. Gate trenches 212 are arranged in the first main surface 110 of the semiconductor wafer. A gate electrode 210 is arranged in the gate trenches 212. The gate electrode 210 is insulated from adjacent semiconductor material 220 by means of a gate dielectric layer 211. The gate electrodes 210 of the shown transistor cells are connected parallel to each other and may be electrically connected to a gate terminal. The source region 201 and the drain region 205 may be of a first conductivity type. The body region 220 of the second conductivity type is disposed adjacent to the source region 201 and adjacent to the gate dielectric layer 211.

The transistor cell 200i further comprises a drift zone 260 which is disposed between the body region 220 and the drain region 205. A front side metallization layer 150 is electrically connected to the source regions 201 and is further electrically connected to the body region 220 by a body contact portion 225. The body contact portion 225 suppresses or deteriorates a parasitic bipolar transistor which may be formed at this position. The front side metallization or conductive layer 150 is electrically connected via the needle 401 to the probe card 400. A back side metallization or conductive layer 206 is arranged in contact with the second main surface 120 of the semiconductor wafer 100 so as to electrically contact the drain region 205. The wafer chuck 300 is in electrical contact with the back side metallization or conductive layer 206.

When the transistor is switched on, e.g. by applying a corresponding voltage to the gate electrode 210, a conductive channel (conductive inversion layer) 215 is formed in the body region 220 at an interface to the gate dielectric layer 211. When the transistor is switched off, e.g. by applying a corresponding or no voltage to the gate electrode 210 no conductive inversion layer forms at the interface and, consequently, no current flows. When performing a test of the transistor 200, a voltage may be applied between the needle 401 and the wafer chuck 300. Alternatively, a current may be impressed between the needle 401 and the wafer chuck 300.

FIG. 2 merely illustrates an example of a power device to be tested. According to further embodiments, different power devices such as IGBTs or diodes may be tested. According to still further embodiments, any kind of semiconductor device may be tested.

In order to improve the quality and the reliability of the manufactured semiconductor devices, it is desirable to perform a dynamic test of the power devices. A dynamic test of a power device involves applying a high current or high voltages. For example, when a power transistor is to be tested, a current of more than 50 A, e.g. 100 A may be impressed. Further, a voltage of several thousand volts, e.g. more than 3000 or 4000 V, such as 5000 V may be applied. Single chips may be fails and a short circuit condition on the failed device may occur on the test arrangement. As a consequence, a very large amount of energy that has been stored for testing will heat up the high ohmic parts of the test arrangement. The high ohmic parts of the test arrangements may be in particular the contacts on the front side and back side of the device. Thus, when the devices are tested at a high power, high temperatures may be generated.

As will be discussed in the following, a wafer chuck that is configured to support a wafer during a wafer test procedure comprises a contact portion for supporting the wafer while being in contact with the wafer. The contact portion is made of a conductive material and the conductive material has a melting point larger than 1500° C. According to a further embodiment, the conductive material may have a melting point larger than 2000° C. As a result, the backside metallization and the chuck metallization may be prevented from welding together. According to embodiments, the wafer chuck may comprise a contact portion that is configured to support the wafer. When the wafer chuck supports the wafer, the contact portion is in contact with the wafer. Differently stated, the portion of the wafer chuck that actually contacts the wafer while the wafer is supported by the wafer chuck, is referred to as the contact portion. FIGS. 3A and 3B show examples of wafer chucks according to embodiments. According to the embodiment shown in FIG. 3A, the wafer chuck 300 is made of a conductive material having a melting point larger than 1500° C. or higher than 2000° C. The wafer chuck 300 comprises a plurality of holes 305 to create a vacuum between the wafer and the wafer chuck 300. According to the embodiment of FIG. 3B, the wafer chuck 300 comprises a core portion 320 and a contact portion 310 which is made of a conductive material having a melting point larger than 1500° C. or larger than 2000° C. According to embodiments, the contact portion 310 may be a layer or a coating of a contact material over the core portion 320, e.g. between the core portion 320 and the wafer 100. For example, a thickness of the contact portion 310 may be several μm to 50 μm. For example, the contact material may comprise a refractor metal such as tungsten (W), tantalum (Ta), molybdenum (Mo), titanium (Ti), vanadium (V), chromium (Cr) etc or an alloy thereof. Further examples comprise metal nitrides of any of these metals, e.g. refractory metals or metal carbides of any of these metals, e.g. refractory metals.

According to the embodiment of FIG. 3B the core portion may comprise Ni or another suitable base metal and may be coated with the coating of any of these conductive materials. For example, the contact portion 310 may be disposed on a surface of the core portion 320.

For example tungsten, which has a melting point of 3422° C. and a low electrical resistivity of 52 nOhmm, a thermal conductivity of 174 W/mK and a heat capacity of 24 J/molK may be used as a material of the contact portion 310. According to a further embodiment, carbon having a melting point of 4000° K to 5000° K at high pressure may be used. At normal pressure, carbon is not melting but sublimating. For example, when using carbon as the contact material, the power tests may be performed under an inert atmosphere to minimize the formation of carbon monoxide or carbon dioxide.

According to further embodiments, alloys, e.g. high entropy alloys may be employed as a material of the contact portion 310. For example, the entire wafer chuck 300 or merely a contact portion 310 over a core portion 320 may be made of a high entropy alloy. High entropy alloys are materials that are made of equal or nearly equal quantities of five or more metals.

According to further embodiments, the material of the contact portion is selected so as to be inert with respect to silicon and/or the material of the back side metallization.

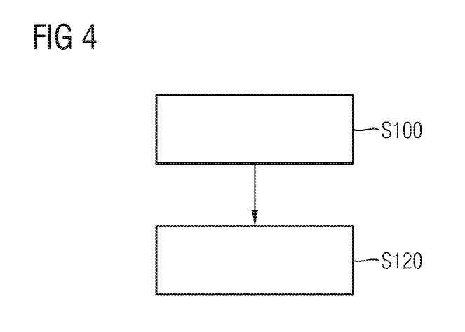

FIG. 4 illustrates a method for testing a semiconductor wafer according to an embodiment. As is shown, a method for testing a wafer comprises placing (S100) the semiconductor wafer on a wafer chuck as has been explained above and impressing a current or applying a voltage (S120) to terminals electrically connected to the semiconductor wafer. For example, the terminals may be electrically connected to opposing sides of the semiconductor wafer. Due to the fact that even if a short-circuit occurs due to failing of a device under test, the wafer chuck is not likely to melt, higher currents than conventionally achieved may be impressed or higher voltages may be applied. According to embodiments, more than 80% or 90% or even more than 94% of the nominal current of the device to be tested may be impressed. In particular, the nominal current is defined as the maximum amount of the power device may carry before sustaining immediate or progressive deterioration. The nominal current is included in the data sheet of the device and depends on the specific device under test. For example, a temperature generated during testing the semiconductor wafer may be more than 1500° C. or more than 2000° C. As a result, the wafer chuck may withstand the high temperatures and may not weld together with the semiconductor wafer.

For example, an avalanche test may be performed. According to the avalanche test, the power transistor is switched on and a high current is flowing between source and drain. Thereafter, the transistor is switched off by applying a corresponding gate voltage. The inductive elements will further drive the current and generate high voltages. Eventually, a break down occurs which generates a short-circuit. In this case, even though the product of U*I is very large, the wafer chuck will not melt nor will it react with the semiconductor wafer. As a result, the semiconductor device may be tested under a high current/voltage condition without the risk of deteriorating the wafer chuck. As a result, the quality of the test may be further improved. Further, due to the better quality of the wafer test, less development time for new method generations may be achieved. As a further result, the control of the process line may be improved. Still further, the quality of the delivered power semiconductor devices may be improved.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

What is claimed is:

1. A wafer chuck comprising:
a contact portion for supporting a wafer while being in contact with the wafer during a wafer test procedure,
the contact portion being made of a conductive material,
the conductive material having a melting point larger than 1500° C.

2. The wafer chuck according to claim 1, wherein the conductive material has a melting point larger than 2000° C.

3. The wafer chuck according to claim 1, wherein the conductive material comprises a refractory metal or an alloy of refractory metals.

4. The wafer chuck according to claim 1, further comprising a core portion, the contact portion being disposed on a surface of the core portion.

5. The wafer chuck according to claim 1, being made of the conductive material.

6. The wafer chuck according to claim 1, wherein the conductive material is inert with respect to silicon.

7. The wafer chuck according to claim 1, wherein the conductive material is selected from the group of tungsten, tantalum, molybdenum, carbides of these materials, nitrides of these materials, and mixtures thereof.

8. The wafer chuck according to claim 1, wherein the conductive material comprises a high entropy alloy.

9. A method of using the wafer chuck according to claim 1, the wafer comprising power semiconductor devices.

10. A wafer chuck comprising:
a core portion for supporting a wafer; and
a contact portion disposed over the core portion, the contact portion being thinner than the core portion and comprising a different material than the core portion, the contact portion comprising a contact surface configured to directly contact a major surface of the wafer, the contact portion comprising a refractory metal element.

11. The wafer chuck of claim 10, wherein the contact portion has a higher melting point than the core portion.

12. The wafer chuck of claim 10, wherein the refractory metal element comprises tungsten (W), tantalum (Ta), molybdenum (Mo), titanium (Ti), vanadium (V), or chromium (Cr).

13. The wafer chuck of claim 12, wherein the core portion comprises nickel.

14. The wafer chuck of claim 12, wherein the melting point of the contact portion is greater than 1500° C. and the melting point of the core portion is less than 1500° C.

15. The wafer chuck of claim 10, further comprising holes in the contact portion.

16. The wafer chuck of claim 10, further comprising holes extending from the contact surface of the contact portion through the core portion.

17. A method for testing a semiconductor wafer comprising:
placing the semiconductor wafer on a wafer chuck, the wafer chuck comprising:
a contact portion for supporting the semiconductor wafer while being in contact with the semiconductor wafer during a wafer test procedure, the contact portion being made of a conductive material, the conductive material having a melting point larger than 1500° C.; and
impressing a current or applying a voltage to terminals electrically connected to the semiconductor wafer.

18. The method according to claim 17, wherein a current is more than 80% of the nominal current.

19. The method according to claim 18, wherein the current is more than 90% of the nominal current.

20. The method according to claim 17, wherein a temperature generated during testing the semiconductor wafer is more than 1500° C.

21. The method according to claim 20, wherein the temperature generated during testing the semiconductor wafer is more than 2000° C.
